(19) United States
(12) Patent Application Publication
(10) Pub. No.: US 2012/0248598 A1
(43) Pub. Date: Oct. 4, 2012

(54) SEMICONDUCTOR BONDING APPARATUS

(75) Inventor: Kuniaki Sueoka, Kanagawa-ken (JP)

(73) Assignee: INTERNATIONAL BUSINESS MACHINES CORPORATION, Armonk, NY (US)

(21) Appl. No.: 13/423,552

(22) Filed: Mar. 19, 2012

(30) Foreign Application Priority Data
Mar. 31, 2011 (JP) 2011079874

(51) Int. Cl. H01L 23/498; B23K 3/04; H01L 21/66

(52) U.S. Cl. 257/737; 438/17; 228/46; 257/E23.068; 257/E21.531

(57) ABSTRACT

An apparatus includes a tool head configured for bonding to establish 100 or more electrical and mechanical connections between a silicon chip having a thickness of about 50 microns (μm) or smaller and a substrate, wherein 100 or more solder bumps set on a plurality of contacts on the silicon chip or a plurality of contacts on the substrate are melted by heating between the plurality of contacts of the silicon chip and the substrate, and wherein the melted solder bumps are solidified by cooling using forced convection of air flowing from around the silicon chip. The tool head includes a pyrolytic graphite sheet configured to be used in direct contact with the silicon chip, and having a thickness between about 75 μm and 125 μm.

### STATEMENT OF GOVERNMENT INTEREST

This invention was made with Government support under Contract Number 08001702-0. The U.S. Government has certain rights to this invention as provided for by the terms of the contract.

### PRIORITY

This application claims priority to Japanese Patent Application No. 2011-079874, filed 31 Mar. 2011, and all the benefits accruing therefrom under 35 U.S.C. §119, the contents of which in its entirety are herein incorporated by reference.

### BACKGROUND

The present invention relates to bonding of semiconductor silicon (Si) chips, and more particularly to a bonding technique for bonding thin Si chips onto a substrate while achieving reduction in a stress generated in contact portions of the chips and the substrate through processes in which fine (solder) bumps are melted by heating and solidified by cooling.

In recent years, higher integration and even three-dimensional integration of electronic circuits have been advanced. With the necessity to increase a band width for interconnection between multiple chips forming a Si stacking, the three-dimensional integration requires designing of fine through silicon vias (TSVs). In order to achieve formation of fine TSVs, each silicon chip itself naturally needs to be made thinner.

Making silicon chips thinner is preferable to enhance the yield of TSV manufacturing. On the other hand, thin silicon chips naturally require considerations as follows. First, a thin silicon chip itself is deformed easily, and therefore has a residual stress generated easily. In addition, a thin silicon chip is warped or distorted easily due to a thermal stress generated with temperature change due to differences in coefficient of thermal expansion (CTE) among multiple materials used for inner parts, such as silicon, wires for inner interconnection, and materials for passivation.

In particular, the thin silicon chip is subjected to a temperature change cycle of heating and cooling all the time through the bonding process, which is a large stress. In addition, the silicon chip receives a pressure for fixing the silicon chip to the substrate. In sum, the silicon chip continuously receives the thermal stress and the mechanical stress, and thus needs to be handled with much greater care.

Existing chip mount methods use a high thermal conductive material such as graphite. Other approaches use a known example of a bonding tool using a high thermal conductive diamond coated film and the like.

### SUMMARY

In one embodiment, an apparatus includes a tool head configured for bonding to establish 100 or more electrical and mechanical connections between a silicon chip having a thickness of about 50 microns (μm) or smaller and a substrate, wherein 100 or more solder bumps set on a plurality of contacts on the silicon chip or a plurality of contacts on the substrate are melted by heating between the plurality of contacts of the silicon chip and the substrate, and wherein the melted solder bumps are solidified by cooling using forced convection of air flowing from around the silicon chip. The tool head includes a pyrolytic graphite sheet configured to be used in direct contact with the silicon chip, and having a thickness between about 75 μm and 125 μm.

### BRIEF DESCRIPTION OF DRAWINGS

FIGS. 1A, 1B, and 1C are diagrams showing a basic configuration of objects to be bonded and a bonding tool (a bonder) to which the present invention is applied.

FIGS. 2A, 2B, and 2C are diagrams for explaining multiple distortions of a silicon chip and influence thereof as a result of deformation of a silicon chip due to bonding with a conventional aluminum nitride (AlN) tool head

FIG. 3 is a diagram showing a principal structure according to the present invention.

FIG. 4 is a diagram schematically showing a heat flow in a case of bonding by the bonder having a tool head of the bonding tool to which the principal structure according to the present invention is applied.

FIG. 5 is a graph for explaining tests of a thin chip bonded by use of a PGS tool head according to the present invention.

FIG. 6 is a perspective view of a surface of a silicon chip having a thickness of 30 μm, and shows a result of bonding the silicon chip by use of the conventional MN tool head.

FIG. 7 is a perspective view of a surface of a silicon chip having a thickness of 30 μm, and shows a result of bonding the silicon chip by use of the PGS tool head according to the present invention.

FIG. 8 is a perspective view of a PGS tool head.

### DETAILED DESCRIPTION

None of the above described approaches address reducing a stress generated in bonding thin silicon chips, as is addressed in the present disclosure. Specifically, the previous approaches differ from the present embodiments particularly in “thinness” scale of a silicon chip or the like to be targeted.

In brief, the present invention embodiments provide a semiconductor bonding apparatus of bonding a thin SI chip to a substrate while achieving reduction in a stress generated in contact portions of the chip and substrate through processes in which fine (solder) bumps are melted by heating and solidified by cooling.

Electrical and mechanical connections between a silicon chip having a thickness of 50 μm or smaller and a substrate in a way that 100 or more solder bumps set on multiple contacts on the silicon chip or multiple contacts on the substrate are melted by heating between the multiple contacts of the silicon chip and the substrate, and that the melted solder bumps are solidified by cooling mainly using forced convection of air flowing from around the silicon chip. A tool head for the above process includes a pyrolytic graphite sheet (PGS) which has a thickness between 75 μm and 125 μm and is to be used in direct contact with the silicon chip.

According to the present invention embodiments, a stress generated in contact portions between a thin silicon chip onto a substrate in the bonding thereof can be reduced, the stress being generated through melting of fine (solder) bumps by heating and solidification thereof by cooling.

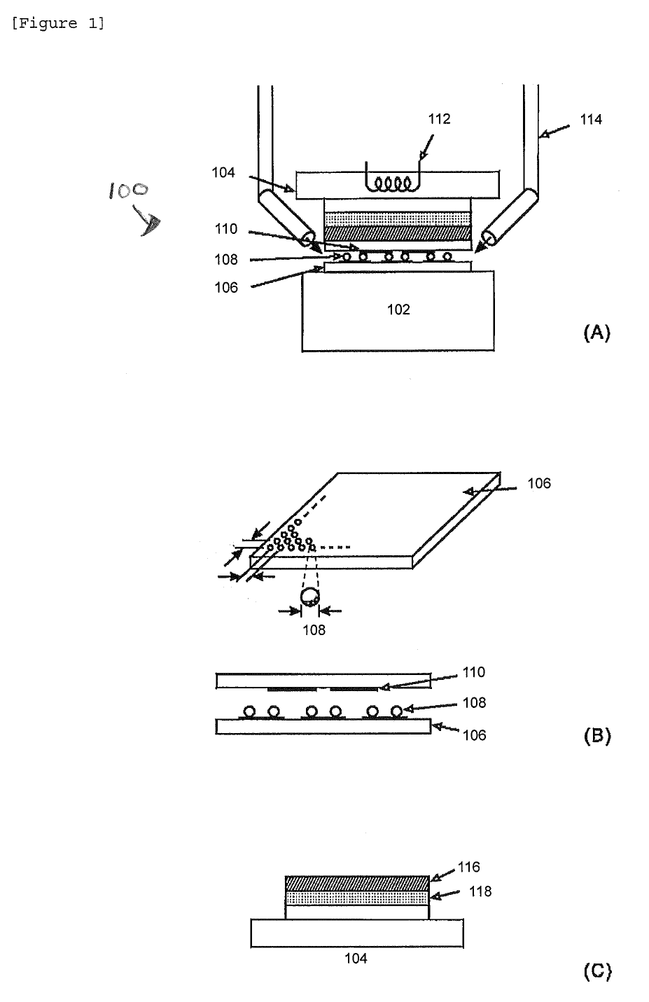

FIGS. 1A, 1B, and 1C are diagrams showing a basic configuration of objects to be bonded and a bonding tool 100 to which the present embodiments are applied.

As shown in FIG. 1A, the bonding tool 100 includes a stage 102 on which objects to be bonded are set and supported and a tool head 104 to apply heat and pressure to the objects set on the stage 102 while being in contact with the objects. Although various objects may be bonded by the bonding tool 100, the description herein uses the example that the object set on the stage 102 is a substrate 106.

A technical significance of a bonding process is to electrically and mechanically connect multiple fine (solder) bumps 108 to multiple (metal) contact portions on the substrate 106 by melting, solidifying and fixing the bumps to the contact portions.

As shown in FIG. 1B, an array of multiple (solder) bumps 108 is prepared on the metal contact portions on a surface of the substrate (a surface on the silicon chip 110 in some cases). As for the number of the (solder) bumps forming the array, 100 (10×10) or more (solder) bumps are arranged over a two-dimensional plane. In one embodiment, an array having even about 28000 (≈16×169) (solder) bumps is achieved.

An array described in an exemplary embodiment achieves such a very high integration that a pitch of arranged (solder) bumps is about 40 μm and a diameter of each (solder) bump is about 25 μm. In such high integration, multiple solder bumps to be bonded are arranged on a two-dimensional plane at a density of 625 solder bumps or more per square millimeter.

The pitch of the (solder) bumps needs to be larger than the diameter of each (solder) bump. Further, in consideration of accuracy of alignment of the silicon chip 110 and the substrate, the pitch needs to be determined so as to prevent adjacent (solder) bumps in the array from fusing together when the (solder) bumps are melted. In this respect, a regular pitch is not necessarily required.

When the array is formed as described above at a density in the order of a diameter of each (solder) bump of 50 μm or smaller and 100 or more (10×10) (solder) bumps forming the array on a two-dimensional plane, there arises special handling difficulty which is completely unexpected in a case where a (solder) bump has a diameter of approximately 70 μm or larger.

Heat at a temperature high enough to melt the (solder) bump is applied to the tool head through an incorporated pulse heater 112 or the like. Generally, a melting point of a tin-silver (solder) bump is approximately between 232° C. and 233° C., although it depends on the composition thereof. For this reason, the tool head 100 is heated to approximately 260° C. to 280° C. including a margin of about 20° C. to 30° C. It should be noted that excessive margin facilitates formation of an intermetallic compound state and also leads to unnecessary energy consumption for cooling.

Solidification of (solder) bumps requires removing the heat therefrom. Slow cooling for a long time such as waiting until naturally cooled is preferable in that thermal and mechanical stresses are less likely to be generated. However, the slow cooling is not efficient from the viewpoint of a turnaround time of a bonding step, that is, a yield. Thus, any forced cooling method is generally prepared.

For example, a method in which a coolant (a liquid such as water) is circulated inside the tool head may be used. However, providing a heat-sink-like mechanism in a small surface area of a small silicon chip would be difficult, and fine flow paths of the coolant would require complicated piping. Further, the method is not preferable in that the bonding tool has a large scale as a whole.

Hence, the bonder to which the present embodiments are applied performs cooling by circulating air inside the tool head and by blowing cooling air 114 from the outside. The blowing of the cooling air 114 from the outside largely contributes to an air flow amount, and the bumps 108 are cooled mainly by forced convection from around the silicon chip 110.

An alternative conceivable technique for the cooling is to inject a thermal grease to enhance thermal coupling. However, this method makes the bonding tool dirty, and thus is preferably not used also from the viewpoint of environmental protection.

As described above, the existence of a thermal cycle of heating and cooling is a main cause of generating the thermal and mechanical stresses over time.

There is a conventional AlN tool head in which a layer transferring heat is provided for assistance to reduce a difference of temperatures on a plane by making the temperatures even.

For example, as shown in FIG. 1C, a high thermal conductive material 116 is provided. Preferably, a layer formed of the material is fixed to the tool head 104 of the bonder and is used repeatedly by coming into direct contact with silicon chips. Thus, such layer is fixed by a heat-resistant elastic adhesive layer 118 to the tool head 104 in some cases.

AlN is known as a material having an excellent heat dissipation property, an expansion rate matching that of silicon, and a fine crystal structure, and also being excellent in strength and ductility. For this reason, AlN is often used for a semiconductor device, other peripheral parts and the like for applications requiring rapid heating, rapid cooling, and heat dissipation. AlN forming an excellent lap surface and achieving high surface precision has become available.

An example of marketed AlN products has the following properties:

1. Thermal conductivity: 170 to 180 W/m·k

2. Bending strength: 400 MPa

3. Hardness: HV1000, HRA89

4. CTE: 5.0×10⁻⁶/° C. (silicon: 4.2×10⁻⁶/° C.)

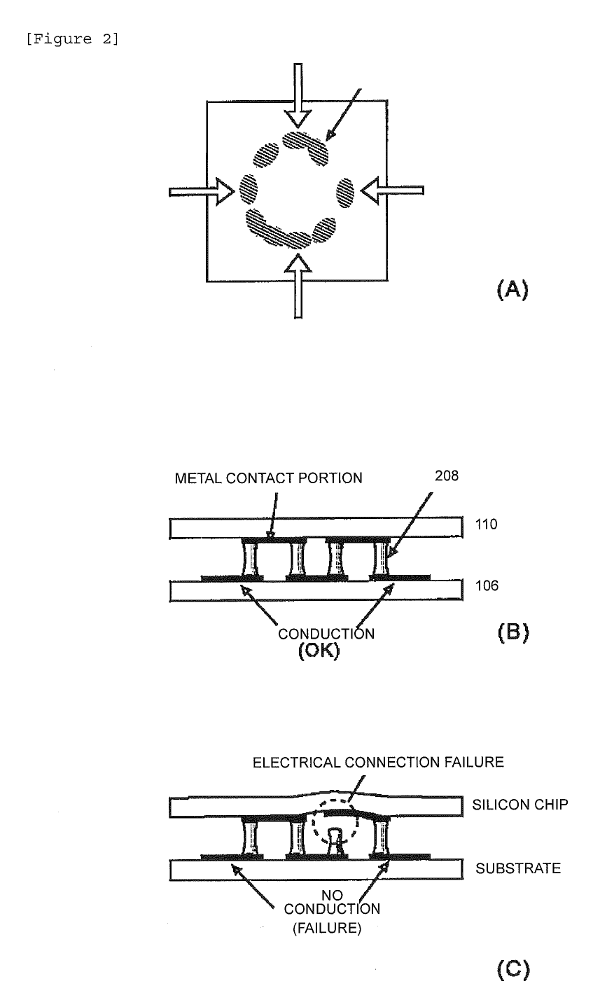

FIGS. 2A, 2B, and 2C are diagrams illustrating multiple distortions of a thin silicon chip and influence thereof as a result of deformation of the silicon chip due to bonding with the conventional AlN tool head. The distortions are generated in the course of solidification of bumps.

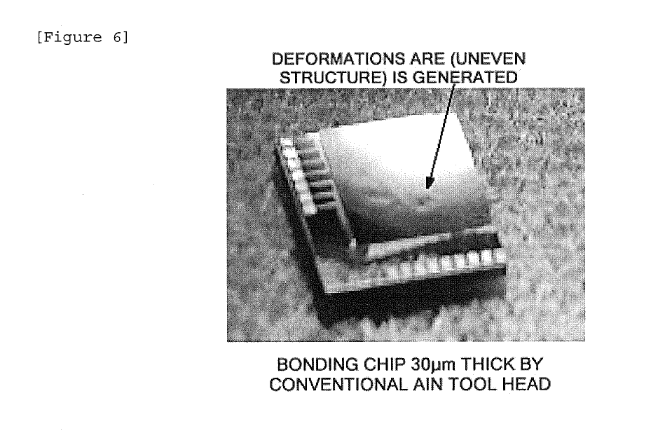

FIG. 2A shows a schematic diagram of the distortions 202. The schematic diagram illustrates a stacked silicon chip having a thickness of 30 μm. Here, an uneven structure is generated in the surface 204 of a stacked silicon chip 206 with an approximately 70 μm thickness and clearly appears in a stacked silicon chip with a 50 μm thickness or smaller. The uneven structure in the surface is illustrated in the schematic diagram in an emphasized manner and will be explained also in FIG. 6 in Example.

It has been determined that the uneven structure is not caused by a surface structure of the tool head, as the shapes of (air) suction holes for the chip are not reflected in the uneven structure. Recessed and protruding portions are arranged radially with respect to the center in an observation thereof. Thus, it is believed that the recessed and protruding portions are generated due to radial non-uniformity of bonding heat temperature.

Specifically, when bumps are cooled forcefully with forced convection from around the silicon chip (to which the blowing of the cooling air from the outside as shown in FIG. 1A largely contributes), a temperature decrease starts from a peripheral portion of the silicon chip, so that the solidification of the (solder) bumps also starts and advances from the peripheral portion of the silicon chip. This is believed to cause the uneven structure.

It is further believed that the radial non-uniformity of bonding heat temperature may make two-dimensional temperature distribution on the silicon chip non-uniform in terms of time and space (orientations on a plane), and therefore may cause the uneven structure.

The uneven structure appears to have a close relationship with the high density of the solder bumps in the order of 100 solder bumps (10×10) or more on the two-dimensional plane. It is believed that the distortions advance toward the center of the silicon chip, are not allowed to escape therefrom, and appear in an annular shape. The cooling air is actually blown from four corner portions (four positions) of the silicon chip.

When such distortions (to be described also with reference to FIG. 6) are observed, it is believed that large stresses may be generated in the multiple contact portions with which the fine solder bumps are to be connected. Thus, there is a concern about breakage (failure in mechanical or electrical connection) due to an occurrence of a crack or the like.

FIG. 2B is a diagram schematically showing a case of proper electrical connection between the silicon chip and the substrate. The (solder) bumps after the melting and solidification electrically connect the silicon chip and the substrate and at the same time mechanically connect and fix the silicon chip to the substrate.

FIG. 2C is a diagram schematically showing a case of a failure in electrical connection between the silicon chip and the substrate. A portion having a distortion (uneven structure) observable from an external surface as shown in FIG. 2C has a high possibility that such a failure in electrical connection occurs in or around the portion.

Whether or not the normal electrical connection has succeeded is checked in a test (after the bonding) for the conduction in a previously set wiring pattern called a daisy chain. A route for checking conduction in FIG. 2C is a schematically shown pattern of the wiring pattern previously set as a part of the daisy chain. FIG. 2B shows a result of the presence of the conduction (OK) or a low resistance, and FIG. 2C shows a result of the absence of the conduction (FAILURE) or a high resistance.

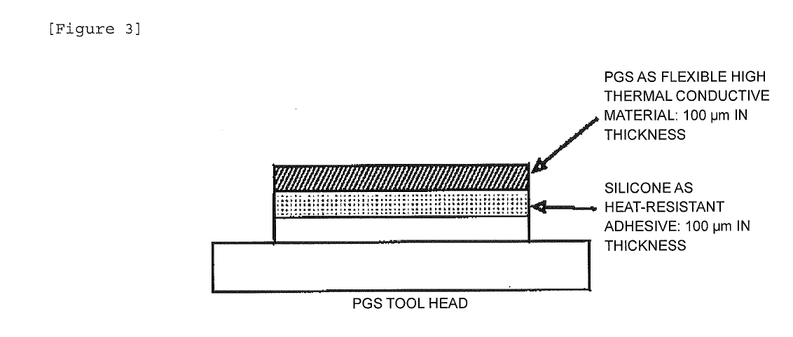

FIG. 3 is a diagram showing a principal structure according to one exemplary embodiment.

In the present embodiments, a layer transferring heat is provided for assistance to reduce the temperature difference (non-uniformity) between the peripheral portion of the silicon chip and the center portion thereof. For this purpose, the use of a material excellent in thermal coupling with the silicon chip is preferable. Thus, the present embodiments use a pyrolytic graphite sheet (PGS) which is flexible and has a high thermal conductivity. The PGS is used for the bonding while being in direct contact with the silicon chip.

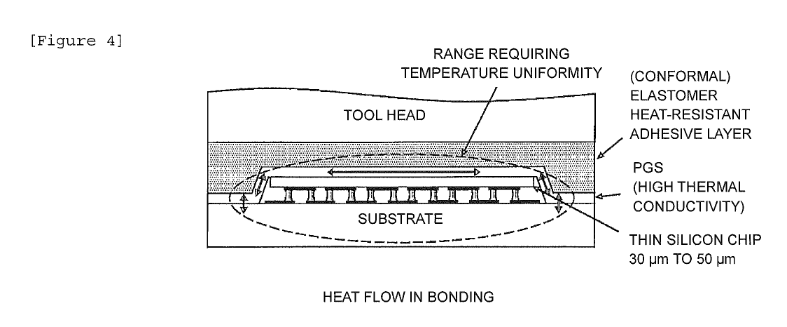

FIG. 4 is a diagram schematically showing a heat flow in a case of bonding by the bonder having a tool head to which the principal structure according to the present invention is applied to a tool head of the bonding tool.

The PGS and the tool head are fixed to each other with a heat-resistant adhesive layer which is an elastomer and has a conformal property. Since an interface between the tool head and the substrate receives a mechanical pressure, the elastomer may serve as a buffer.

The set degree of mechanical pressure influences the thermal conductivity. Generally, application of a high pressure improves the thermal conductivity, but gives a large mechanical stress to the thin silicon chip. In contrast, application of a low pressure cannot promise such a high thermal conductivity, but does not provide a large mechanical stress to the thin silicon chip.

In this respect, if the PGS exerts the conformal property, the conformability can promise an optimum bonding condition for achieving both the high thermal conductivity and minimization of the mechanical strength.

Both surfaces of the PGS and the silicon chip are uneven at a micro level, contact with each other nearly in point contact (aggregation of point contacts), and therefore form an unfavorable thermal coupling from the beginning. In this respect, the utilization of the conformal property of the PGS can further improve the contact state and promise enhancement of the thermal coupling without use of the thermal grease or the like.

While the PGS itself can promise to exert the properties of an elastomer buffer, the heat-resistant adhesive layer releases the pressure applied to the PGS to prevent plastic deformation of the PGS and thus contributes to reuse of the PGS.

### EXAMPLE

The structure used in the present example was a PGS which has a 100 μm thickness and on which a silicone layer (a heat-resistant adhesive layer) having a 100 μm thickness was placed. The silicone layer was used for adhering the PGS to a tool head. Actually, the silicone layer having a lower thermal conductivity than the PGS might not be required, the presence of the silicone layer is preferable in a viewpoint of affinity for adhesion.

Specifically, the following marketed PGS product was used as a PGS layer. Hence, those skilled in the art can obtain the PGS product and perform reproduction and additional tests in accordance with the present example.

“PGS” graphite sheet by Panasonic Corporation, Type: EYGM

Model No.: EYGM131810SS

Type: Silicon layered type, Single-sided

The characteristics of the PGS graphite sheet are disclosed as follows:

Thickness: 0.10±0.05 mm

Density: 1 g/cm³ (cubic centimeters)

Thermal conductivity: 600 to 800 W/(m·K) in plane direction

Extensional strength: 19.6 MPa

Expansion coefficient: plane direction, 9.3×10⁻⁷ (negative seventh power) 1/K

Expansion coefficient: 3.2×10⁻⁵ (negative fifth power) 1/K in thickness direction

Heat resistance: 400° C.

A PGS having a thickness between 75 μm and 125 μm can promise effective thermal coupling. However, a too thin PGS cannot be expected to form the effective thermal coupling utilizing the conformal property. Tests were not performed on PGS's having thicknesses of 50 μm and 25 μm.

In bonding tests, favorable low-resistance connectivity was obtained from silicon chips having thicknesses of 50 μm and 30 μm. In other words, favorable results were obtained in a thickness range at least between 30 μm and 50 μm, and it is inferred that a favorable result could be obtained also in a thickness of 30 μm or smaller. Each silicon chip has a square shape 7 mm on a side. The substrate has a thickness of 720 μm.

Solder bumps having a spherical shape 25 μm in diameter were arranged at a pitch of 40 μm on a two-dimensional surface of the substrate.

Pulse heating of the tool head was employed to heat the solder bumps, and a pressure between 5 N (newton) and 10 N was applied to the solder bumps.

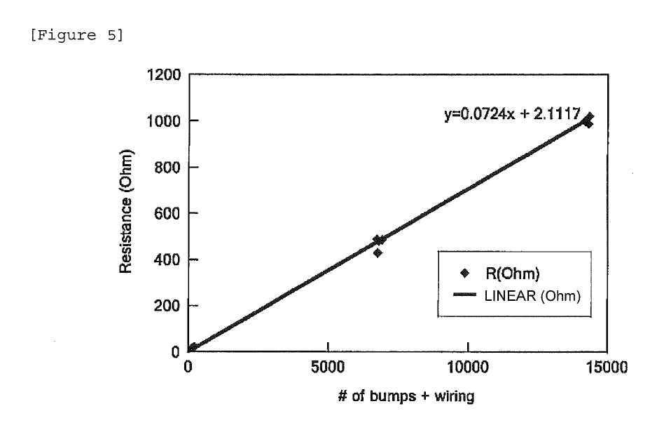

FIG. 5 is a graph for explaining tests of a thin chip bonded by use of a PGS tool head according to one embodiment.

The lengths in a daisy chain and the resistance values corresponding to the lengths were observed, and plotted in FIG. 5 to show whether or not normal electrical connection was succeeded. All the observed plots distribute along a linear line, which shows that the electrical and mechanical connections did not succeed as shown in the schematic diagram in FIG. 2B. A daisy chain connected with at maximum 13000 (solder) bumps was also tested as the previously set wiring pattern.

FIG. 6 is a perspective view of a surface of a silicon chip having a thickness of 30 μm, and shows a result of bonding the silicon chip by use of the conventional AlN tool head.

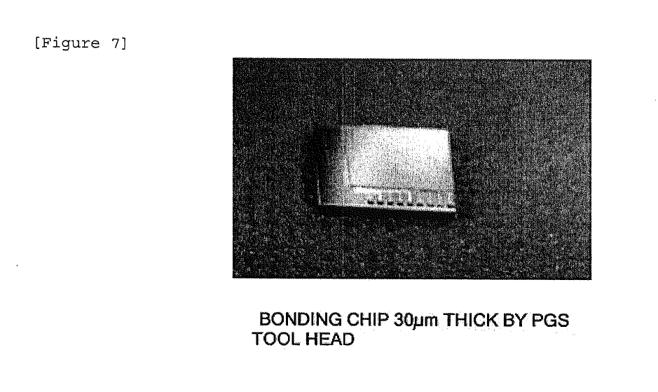

FIG. 7 is a perspective view of a surface of a silicon chip having a thickness of 30 μm, and shows a result of bonding the silicon chip by use of the PGS tool head according to the present invention.

In comparison between FIGS. 6 and 7, the result of the bonding using the conventional AlN tool head in FIG. 6 shows the distortions schematically shown in FIG. 2. In contrast, the result of the bonding using the PGS tool head according to the present invention in FIG. 7 does not show such distortions.

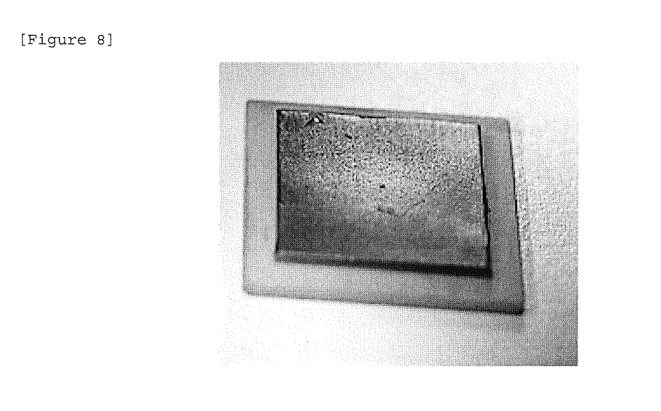

FIG. 8 is a perspective view of the PGS tool head. This PGS tool head has the same structure as in FIG. 3.

1. An apparatus, comprising:
a tool head configured for bonding to establish 100 or more electrical and mechanical connections between a silicon chip having a thickness of about 50 microns (μm) or smaller and a substrate, wherein 100 or more solder bumps set on a plurality of contacts on the silicon chip or a plurality of contacts on the substrate are melted by heating between the plurality of contacts of the silicon chip and the substrate, and wherein the melted solder bumps are solidified by cooling using forced convection of air flowing from around the silicon chip;
the tool head comprising a pyrolytic graphite sheet configured to be used in direct contact with the silicon chip, and having a thickness between about 75 μm and 125 μm.

2. The apparatus according to claim 1, wherein the pyrolytic graphite sheet has a thickness of about 100 μm.

3. The apparatus according to claim 2, further comprising a silicone layer provided as a heat-resistant adhesive between the tool head and the pyrolytic graphite sheet layer, and having a thickness of about 100 μm.

4. The apparatus according to claim 1, wherein the silicon chip to be bonded has a thickness between about 30 μm and 50 μm.

5. The apparatus according to claim 1, wherein the plurality of solder bumps to be bonded are arranged on a two-dimensional plane at a density of about 625 solder bumps per square millimeter.

6. A bonding tool comprising:
a tool head configured for bonding to establish 100 or more electrical and mechanical connections between a silicon chip having a thickness of about 50 microns (μm) or smaller and a substrate, wherein 100 or more solder bumps set on a plurality of contacts on the silicon chip or a plurality of contacts on the substrate are melted by heating between the plurality of contacts of the silicon chip and the substrate, and wherein the melted solder bumps are solidified by cooling using forced convection of air flowing from around the silicon chip, a pyrolytic graphite sheet configured to be used in direct contact with the silicon chip, and having a thickness between about 75 μm and 125 μm; and
a stage on which objects to be bonded together is to be set and supported, wherein the tool head applies a heat and a pressure to the objects set on the stage while being in contact with the objects, and cools the objects mainly by using forced convection of air flowing from around a silicon chip.

7. A structure comprising a silicon chip and a substrate which are electrically and mechanically connected to each other by bonding with the bonding tool (bonder) according to claim 6.

8. (canceled)
